(19) United States
(12) Patent Application Publication
(10) Pub. No.: US 2026/0075826 A1
(43) Pub. Date: Mar. 12, 2026

(54) SEMICONDUCTOR DEVICE AND METHOD OF MANUFACTURING THE SAME

(71) Applicant: Kioxia Corporation, Tokyo (JP)

(72) Inventors: Saori MATSUSHITA, Yokkaichi Mie (JP); Kensei TAKAHASHI, Kuwana Mie (JP)

(73) Assignee: Kioxia Corporation, Tokyo (JP)

(21) Appl. No.: 19/068,139

(22) Filed: Mar. 3, 2025

(30) Foreign Application Priority Data
Sep. 12, 2024 (JP) 2024-158602

(51) Int. Cl. H10B 43/30; H01L 23/00; H01L 25/00; H01L 25/065; H01L 25/18; H10B 43/27; H10B 80/00

(52) U.S. Cl. CPC H10B 43/30; H10B 43/27; H10B 80/00; H10W 90/00; H10W 80/312; H10W 80/327; H10W 90/792

(57) ABSTRACT

In one embodiment, a semiconductor device includes a stacked film including a plurality of electrode layers and a plurality of first insulators that are alternately provided in a first direction. The device further includes a columnar portion extending in the first direction in the stacked film, and including a charge storage layer provided on a side face of the stacked film via a second insulator, and a semiconductor layer provided on a side face of the charge storage layer via a third insulator. A first electrode layer among the plurality of electrode layers includes a first layer including molybdenum, nitrogen, and a Group 14 element, and a second layer including molybdenum.

### CROSS REFERENCE TO RELATED APPLICATION

This application is based upon and claims the benefit of priority from the prior Japanese Patent Application No. 2024-158602, filed on Sep. 12, 2024, the entire contents of which are incorporated herein by reference.

### FIELD

Embodiments described herein relate to a semiconductor device and a method of manufacturing the same.

### BACKGROUND

In a three-dimensional semiconductor memory, an electrode material layer in an electrode layer such as a word line is formed of, for example, a molybdenum (Mo) layer. In this case, a problem is what kind of layer is used to form a barrier metal layer in the electrode layer.

### BRIEF DESCRIPTION OF THE DRAWINGS

FIG. 1 is a perspective view illustrating a structure of a semiconductor device of a first embodiment;

FIGS. 2 to 5 are cross-sectional views illustrating a method of manufacturing the semiconductor device of the first embodiment;

FIGS. 6A and 6B are cross-sectional views illustrating a structure of a semiconductor device of a comparative example of the first embodiment, and the structure of the semiconductor device of the first embodiment;

FIG. 7 is a cross-sectional view illustrating a structure of a semiconductor device of a second embodiment;

FIG. 8 is an enlarged cross-sectional view illustrating the structure of the semiconductor device of the second embodiment; and

FIGS. 9 and 10 are cross-sectional views illustrating a method of manufacturing the semiconductor device of the second embodiment.

### DETAILED DESCRIPTION

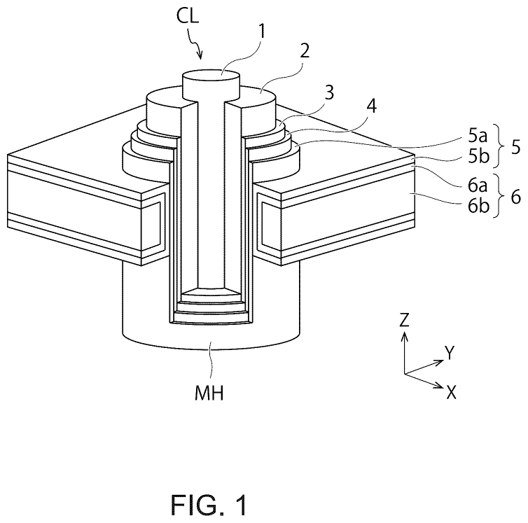

Embodiments will now be explained with reference to the accompanying drawings. The same components in FIGS. 1 to 10 are denoted by the same reference sign, and duplicate description of components is omitted.

In one embodiment, a semiconductor device includes a stacked film including a plurality of electrode layers and a plurality of first insulators that are alternately provided in a first direction. The device further includes a columnar portion extending in the first direction in the stacked film, and including a charge storage layer provided on a side face of the stacked film via a second insulator, and a semiconductor layer provided on a side face of the charge storage layer via a third insulator. A first electrode layer among the plurality of electrode layers includes a first layer including molybdenum, nitrogen, and a Group 14 element, and a second layer including molybdenum.

### First Embodiment

FIG. 1 is a perspective view illustrating a structure of a semiconductor device of a first embodiment. The semiconductor device of the present embodiment is, for example, a three-dimensional semiconductor memory.

The semiconductor device of the present embodiment includes a core insulator 1, a channel semiconductor layer 2, a tunnel insulator 3, a charge storage layer 4, a block insulator 5, and an electrode layer 6. The block insulator 5 includes an insulator 5a and an insulator 5b, and the electrode layer 6 includes a barrier metal layer 6a and an electrode material layer 6b. The barrier metal layer 6a and the electrode material layer 6b are examples of first and second layers, respectively. The channel semiconductor layer 2 is an example of a semiconductor layer. The insulator 5a, the tunnel insulator 3, and the insulator 5b are examples of second, third, and fourth insulators, respectively.

In FIG. 1, a plurality of electrode layers and a plurality of insulators are alternately stacked on a substrate, and a memory hole MH is provided in the electrode layers and the insulators. FIG. 1 illustrates the electrode layer 6 as one of these electrode layers. Each electrode layer functions as, for example, a word line or a selection line of the three-dimensional semiconductor memory. FIG. 1 illustrates an X direction and a Y direction parallel to the surface of the substrate and orthogonal to each other, and a Z direction orthogonal to the surface of the substrate. In the present specification, the +Z direction is an upward direction, and the −Z direction is a downward direction. The −Z direction may or may not be aligned with the direction of gravity. The Z direction is an example of a first direction, and the memory hole MH is an example of a first concave portion. In FIG. 1, the memory hole MH extends in the Z direction and has a circular shape in a plan view.

The core insulator 1, the channel semiconductor layer 2, the tunnel insulator 3, the charge storage layer 4, and the insulator 5a are formed in the memory hole MH and constitute a memory cell of the three-dimensional semiconductor memory. The insulator 5a is formed on the side faces of the electrode layers and the insulators in the memory hole MH, and the charge storage layer 4 is formed on the side face of the insulator 5a. The charge storage layer 4 can store signal electric charge of the three-dimensional semiconductor memory. The tunnel insulator 3 is formed on the side face of the charge storage layer 4, and the channel semiconductor layer 2 is formed on the side face of the tunnel insulator 3. The channel semiconductor layer 2 functions as a channel of the three-dimensional semiconductor memory. The core insulator 1 is formed on the side face of the channel semiconductor layer 2.

The insulator 5a is, for example, a silicon oxide film (SiO₂ film). The charge storage layer 4 is, for example, a silicon nitride film (SiN film). The tunnel insulator 3 is, for example, a SiO₂ film. The channel semiconductor layer 2 is, for example, a polysilicon layer. The core insulator 1 is, for example, a SiO₂ film. In FIG. 1, a columnar portion CL including the core insulator 1, the channel semiconductor layer 2, the tunnel insulator 3, the charge storage layer 4, and the insulator 5a is formed in the memory hole MH. In FIG. 1, the columnar portion CL extends in the Z direction and has a circular shape in a plan view.

The insulator 5b, the barrier metal layer 6a, and the electrode material layer 6b are formed between two insulators among the above-described plurality of insulators and sequentially formed on the upper face of the lower insulator, the lower face of the upper insulator, and the side face of the insulator 5a. Specifically, the barrier metal layer 6a is formed between the lower and upper insulators via the insulator 5b, and is formed on the upper face, lower face, and side face of the insulator 5b. The electrode material layer 6b is formed between the lower and upper insulators via the insulator 5b and the barrier metal layer 6a, and is formed on the upper face, lower face, and side face of the barrier metal layer 6a. The above-described plurality of insulators are examples of first insulators, the lower insulator is an example of a lower-side insulator, and the upper insulator is an example of an upper-side insulator. The electrode layer 6 illustrated in FIG. 1 is an example of a first electrode layer.

The insulator 5b is, for example, an Al₂O₃ film (Al represents aluminum and O represents oxygen). The barrier metal layer 6a is, for example, a MoSiN film (Mo represents molybdenum, Si represents silicon, and N represents nitrogen). The electrode material layer 6b is, for example, a molybdenum (Mo) layer.

Further details of the barrier metal layer 6a and the electrode material layer 6b of the present embodiment will be described below with reference to FIG. 1 again.

The barrier metal layer 6a includes molybdenum, silicon, and nitrogen and may further include one or more other kinds of elements. Examples of such elements include oxygen and hydrogen. The barrier metal layer 6a is, for example, a MoSiN film including oxygen and/or hydrogen as impurity elements. However, the barrier metal layer 6a of the present embodiment preferably includes molybdenum as a main constituent element. For example, in a case where the barrier metal layer 6a includes elements E₁, E₂, . . . , E_{N} (N is an integer equal to or larger than two), the atomic concentration of molybdenum in the barrier metal layer 6a is preferably the maximum concentration among the atomic concentrations C₁, C₂, . . . , C_{N} of the elements E₁, E₂, . . . , E_{N} in the barrier metal layer 6a.

The atomic concentration of nitrogen in the barrier metal layer 6a is, for example, equal to or higher than 20% of the total atomic concentration of molybdenum, silicon, and nitrogen in the barrier metal layer 6a. The atomic concentration of silicon in the barrier metal layer 6a is, for example, equal to or higher than 5% of the total atomic concentration of molybdenum, silicon, and nitrogen in the barrier metal layer 6a. In a case where the barrier metal layer 6a includes hydrogen, the atomic concentration of hydrogen in the barrier metal layer 6a is, for example, equal to or higher than 1.0×10²⁰ atoms/cm³.

The barrier metal layer 6a is, for example, an amorphous layer. The thickness of the barrier metal layer 6a is, for example, equal to or smaller than 3 nm. The present embodiment makes it possible to thin, for example, the electrode layer 6 by thinning the barrier metal layer 6a. In the present embodiment, since the barrier metal layer 6a is thin, the barrier metal layer 6a formed as an amorphous layer does not change to a polycrystalline layer by annealing but remains as an amorphous layer after the annealing. However, the barrier metal layer 6a may be a polycrystalline layer.

The barrier metal layer 6a may include, in place of silicon, a Group 14 element other than silicon. Examples of such a Group 14 element include carbon. Description of the barrier metal layer 6a above and later is also applicable to a case where the barrier metal layer 6a includes, in place of silicon, a Group 14 element other than silicon.

The electrode material layer 6b includes molybdenum and may further include one or more other kinds of elements. Examples of such elements include hydrogen. The electrode material layer 6b is, for example, a Mo layer including hydrogen as an impurity element. However, the electrode material layer 6b of the present embodiment preferably includes molybdenum as a main constituent element. For example, in a case where the electrode material layer 6b includes elements e₁, e₂, . . . , e_{N} (n is an integer equal to or larger than two), the atomic concentration of molybdenum in the electrode material layer 6b is preferably the maximum concentration among the atomic concentrations c₁, c₂, . . . , c_{N} of the elements e₁, e₂, . . . , e_{N} in the electrode material layer 6b.

The atomic concentration of hydrogen in the electrode material layer 6b is, for example, higher than the atomic concentration of hydrogen in the insulator 5a. Further detail of this relation will be described later.

The barrier metal layer 6a and the electrode material layer 6b both include molybdenum. The barrier metal layer 6a and the electrode material layer 6b are formed, for example, by using source gas including molybdenum and chlorine. In this case, the barrier metal layer 6a and the electrode material layer 6b may include chlorine as an impurity element. Hydrogen and oxygen in the barrier metal layer 6a originate from, for example, source gas used to form the barrier metal layer 6a and other layers, and become mixed into the barrier metal layer 6a. Similarly, hydrogen in the electrode material layer 6b originates from, for example, source gas used to form the electrode material layer 6b and other layers, and becomes mixed in the electrode material layer 6b. However, impurity elements in the barrier metal layer 6a and the electrode material layer 6b may originate from causes other than source gas and may originate from, for example, annealing gas.

As described above, the electrode material layer 6b of the present embodiment is formed by using molybdenum. This makes it possible to lower the electric resistance of the electrode material layer 6b. For example, by forming the electrode material layer 6b by using molybdenum, it is possible to lower the electric resistance of the electrode material layer 6b as compared to a case where the electrode material layer 6b is formed by using tungsten or aluminum.

The barrier metal layer 6a of the present embodiment is formed by using molybdenum, silicon, and nitrogen. This makes it possible to suppress diffusion of nitrogen (N) atoms from the barrier metal layer 6a to the electrode material layer 6b, and it is possible to suppress increase in the electric resistance of the electrode material layer 6b due to N atoms. Moreover, it is possible to suppress diffusion of oxygen (O) atoms, hydrogen (H) atoms, chlorine (Cl) atoms, and the like to the block insulator 5 and the charge storage layer 4 through the barrier metal layer 6a, and it is possible to suppress decrease of data retention of the three-dimensional semiconductor memory due to these atoms.

Oxygen and hydrogen in the barrier metal layer 6a originate from, for example, O atoms and H atoms stored in the barrier metal layer 6a without passing through the barrier metal layer 6a. Due to such H atoms, the barrier metal layer 6a includes H atoms at high concentration of 1.0×10²⁰ atoms/cm³ or higher, for example, in some cases. The relation that the atomic concentration of hydrogen in the electrode material layer 6b is higher than the atomic concentration of hydrogen in the insulator 5a is due to, for example, a large number of H atoms being stored in the electrode material layer 6b without passing through the barrier metal layer 6a. Further detail of diffusion of these atoms will be described later.

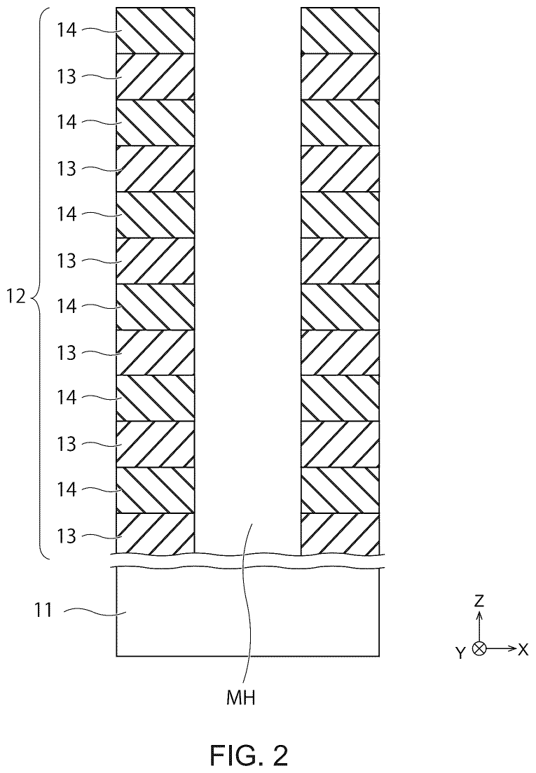

FIGS. 2 to 5 are cross-sectional views illustrating a method of manufacturing the semiconductor device of the first embodiment.

First, a stacked film 12 is formed on a substrate 11 (FIG. 2). The stacked film 12 includes a plurality of sacrifice layers 13 and a plurality of insulators 14, the layers and films being alternately formed in the Z direction. The stacked film 12 is formed by alternately stacking the sacrifice layers 13 and the insulators 14 on the substrate 11. The stacked film 12 may be directly formed on the substrate 11 or may be formed on the substrate 11 via another layer. The substrate 11 is, for example, a semiconductor substrate such as a silicon (Si) substrate. The sacrifice layers 13 is, for example, a SiN film. The insulators 14 is, for example, a SiO₂ film. The sacrifice layers 13 is an example of a third layer. The insulators 14 are examples of the first insulators.

Subsequently, a plurality of memory holes MH are formed in the stacked film 12 by photolithography and reactive ion etching (RIE) (FIG. 2). FIG. 2 illustrates one of the memory holes MH. Each memory hole MH of the present embodiment extends in the Z direction and penetrates through the stacked film 12. Each memory hole MH is an example of the first concave portion.

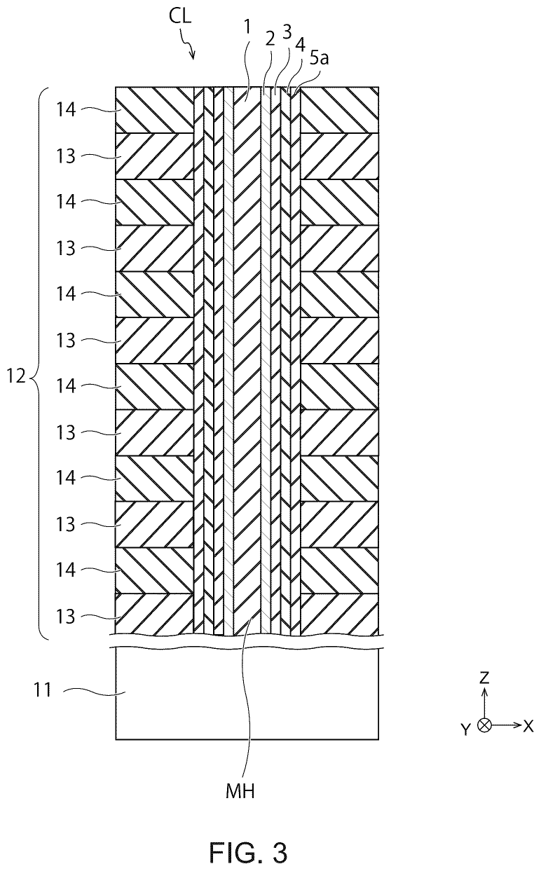

Subsequently, the insulator 5a, the charge storage layer 4, the tunnel insulator 3, the channel semiconductor layer 2, and the core insulator 1 are sequentially formed on the side face of the stacked film 12 in each memory hole MH (FIG. 3). As a result, a plurality of columnar portions CL are formed in the plurality of memory holes MH. FIG. 3 illustrates one of the columnar portions CL. Each columnar portion CL of the present embodiment extends in the Z direction and penetrates through the stacked film 12. In each columnar portion CL, the charge storage layer 4 is formed on the side face of the above-described plurality of sacrifice layers 13 and insulators 14 via the insulator 5a, and the channel semiconductor layer 2 is formed on the side face of the charge storage layer 4 via the tunnel insulator 3.

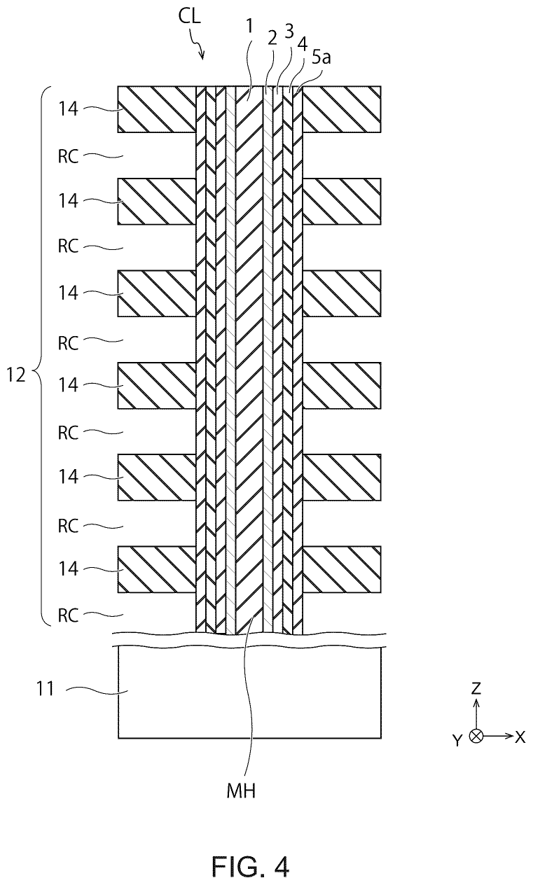

Subsequently, a plurality of slits (not illustrated) are formed in the stacked film 12, and the sacrifice layers 13 is removed through these slits by using drug solution such as phosphoric acid water solution. As a result, a plurality of hollow spaces RC are formed in the stacked film 12 (FIG. 4).

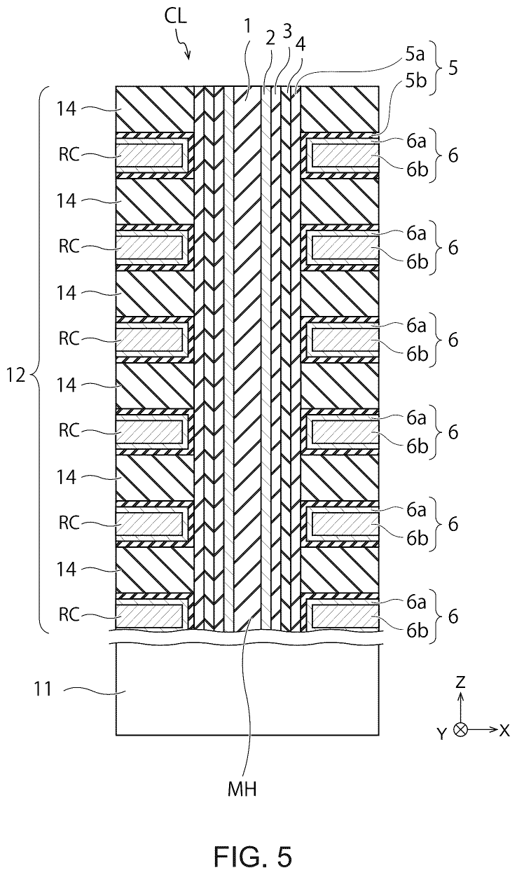

Subsequently, the insulator 5b, the barrier metal layer 6a, and the electrode material layer 6b are sequentially formed on the surfaces of the insulators 5a and 14 in each hollow space RC (FIG. 5). As a result, the block insulator 5 including the insulators 5a and 5b is formed. In addition, the electrode layer 6 including the barrier metal layer 6a and the electrode material layer 6b is formed in each hollow space RC. In addition, the stacked film 12 alternately including the plurality of electrode layers 6 and the plurality of insulators 14 is formed on the substrate 11. In this manner, a replacement process of replacing the sacrifice layers 13 with the electrode layers 6 is performed.

Each hollow space RC is formed between two insulators 14 adjacent to each other in the Z direction. In each hollow space RC, the insulator 5b, the barrier metal layer 6a, and the electrode material layer 6b are sequentially formed on the upper face of the lower insulator 14, the lower face of the upper insulator 14, and the side face of the insulator 5a. The lower insulator 14 is an example of the lower-side insulator, and the upper insulator 14 is an example of the upper-side insulator. Each electrode layer 6 illustrated in FIG. 5 is an example of the first electrode layer.

In this manner, the semiconductor device of the present embodiment is manufactured (FIG. 5). FIG. 1 illustrates a part of the semiconductor device illustrated in FIG. 5.

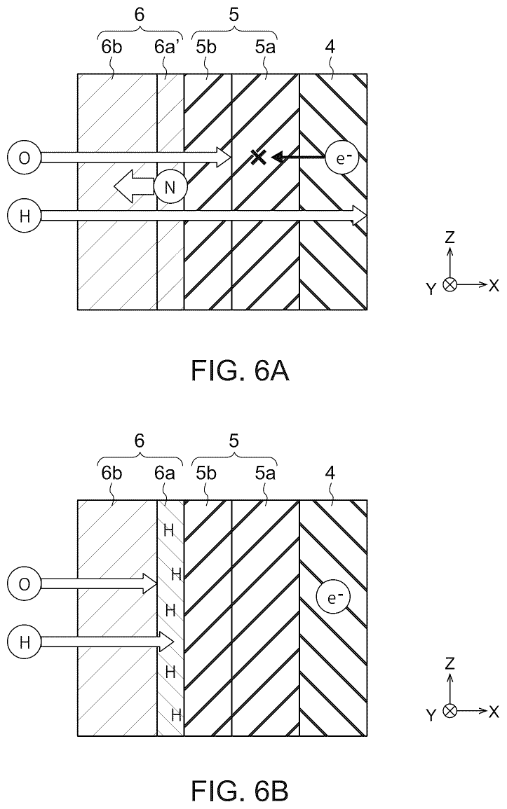

FIGS. 6A and 6B are cross-sectional views illustrating a structure of a semiconductor device of a comparative example of the first embodiment, and the structure of the semiconductor device of the first embodiment.

FIG. 6A illustrates the charge storage layer 4, the block insulator 5, and the electrode layer 6 in the semiconductor device of the comparative example. The electrode layer 6 of the comparative example includes a barrier metal layer 6a′ in place of the barrier metal layer 6a of the first embodiment and also includes the electrode material layer 6b as in the first embodiment. The barrier metal layer 6a′ of the comparative example is, for example, a MoN film. The electrode material layer 6b of the comparative example is, for example, a Mo layer.

In a case where the barrier metal layer 6a′ is a MoN film, N atoms included in the barrier metal layer 6a′ are likely to diffuse to the electrode material layer 6b as illustrated in FIG. 6A. Accordingly, the electric resistance of the electrode material layer 6b increases, which is a problem.

In a case where the barrier metal layer 6a′ is a MoN film, O atoms and H atoms are likely to diffuse to the block insulator 5 and the charge storage layer 4 through the barrier metal layer 6a′ as illustrated in FIG. 6A. This is the same for Cl atoms, for example. Accordingly, these atoms reduce data retention of the three-dimensional semiconductor memory, which is a problem. For example, OH radicals are generated in the block insulator 5 and electrons (e⁻) escape from the charge storage layer 4 through the OH radicals, which is a problem.

FIG. 6B illustrates the charge storage layer 4, the block insulator 5, and the electrode layer 6 in the semiconductor device of the first embodiment. As described above, the electrode layer 6 of the present embodiment includes the barrier metal layer 6a and the electrode material layer 6b. The barrier metal layer 6a of the present embodiment is, for example, a MoSiN film. The electrode material layer 6b of the present embodiment is, for example, a Mo layer.

The barrier metal layer 6a of the present embodiment includes Si atoms in addition to N atoms. This makes it possible to suppress diffusion of N atoms included in the barrier metal layer 6a to the electrode material layer 6b as illustrated in FIG. 6B, and makes it possible to suppress increase in the electric resistance of the electrode material layer 6b due to N atoms.

The present embodiment makes it possible to trap H atoms or the like by the barrier metal layer 6a including Si atoms as illustrated in FIG. 6B. This makes it possible to suppress diffusion of H atoms or the like to the block insulator 5 and the charge storage layer 4 through the barrier metal layer 6a, and makes it possible to suppress decrease of data retention of the three-dimensional semiconductor memory due to H atoms or the like. For example, it is possible to suppress generation of OH radicals in the block insulator 5, and it is possible to suppress escape of electrons (e⁻) from the charge storage layer 4 through the OH radicals.

As described above, each electrode layer 6 of the present embodiment includes the barrier metal layer 6a including molybdenum, silicon, and nitrogen, and the electrode material layer 6b including molybdenum. Thus, the present embodiment makes it possible to form preferable electrode layers 6 by, for example, suppressing performance decrease of the semiconductor device due to the barrier metal layers 6a.

In a case where the semiconductor device of the present embodiment is manufactured by bonding two or more substrates including the substrate 11, the semiconductor device of the present embodiment does not necessarily need to include the substrate 11. Such an example of the semiconductor device will be described below in a second embodiment.

### Second Embodiment

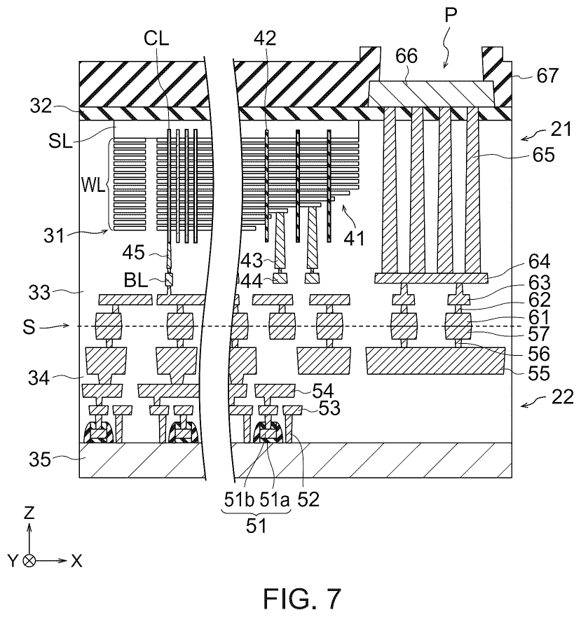

FIG. 7 is a cross-sectional view illustrating a structure of a semiconductor device of the second embodiment. The semiconductor device of the present embodiment is, for example, a three-dimensional semiconductor memory.

The semiconductor device of the present embodiment includes an array chip 21 and a circuit chip 22 bonded to each other. As described later, the semiconductor device of the present embodiment is manufactured by bonding an array wafer including the array chip 21 and a circuit wafer including the circuit chip 22.

The array chip 21 includes a memory cell array 31 including a plurality of memory cells, an insulator 32 on the memory cell array 31, and an inter layer dielectric 33 below the memory cell array 31. The insulator 32 is, for example, a SiO₂ film. The inter layer dielectric 33 is, for example, a stacked film including a SiO₂ film and other insulators. A part of the memory cell array 31 of the present embodiment corresponds to the stacked film 12 of the first embodiment.

The circuit chip 22 is provided below the array chip 21. Reference sign S denotes a bonding face of the array chip 21 and the circuit chip 22. The circuit chip 22 includes an inter layer dielectric 34 below the inter layer dielectric 33, and a substrate 35 below the inter layer dielectric 34. The inter layer dielectric 34 is, for example, a stacked film including a SiO₂ film and other insulators. The substrate 35 is, for example, a semiconductor substrate such as a Si substrate.

FIG. 7 illustrates an X direction and a Y direction parallel to the surface of the substrate 35 and orthogonal to each other, and a Z direction orthogonal to the surface of the substrate 35. The X direction, the Y direction, and the Z direction intersect one another. In the present embodiment, as in the first embodiment, the +Z direction is the upward direction, and the −Z direction is the downward direction. The −Z direction may or may not be aligned with the direction of gravity.

The array chip 21 includes a plurality of word lines WL as a plurality of electrode layers in the memory cell array 31. FIG. 7 illustrates a staircase structure portion 41 in the memory cell array 31, and a plurality of beam portions 42 provided in the staircase structure portion 41. Each word line WL extends in the X direction and is electrically connected to a word interconnect layer 44 through a contact plug 43. Each columnar portion CL penetrating through the plurality of word lines WL is electrically connected to a bit line BL through a via plug 45 and electrically connected to a source line SL. The bit line BL extends in the Y direction and is provided below the plurality of word lines WL. The source line SL extends in the X direction and is provided above the plurality of word lines WL.

The circuit chip 22 includes a plurality of transistors 51. Each transistor 51 includes a gate insulator 51a and a gate electrode 51b sequentially provided on the substrate 35, and a source diffusion layer and a drain diffusion layer provided in the substrate 35, which are not illustrated. The circuit chip 22 includes a plurality of contact plugs 52 each provided on the gate electrode 51b, the source diffusion layer, or the drain diffusion layer of the corresponding one of the plurality of transistors 51. The circuit chip 22 also includes an interconnect layer 53, an interconnect layer 54, and an interconnect layer 55. The interconnect layer 53 includes a plurality of interconnects and is provided on the plurality of contact plugs 52. The interconnect layer 54 includes a plurality of interconnects and is provided on the interconnect layer 53. The interconnect layer 55 includes a plurality of interconnects and is provided on the interconnect layer 54.

The circuit chip 22 further includes a plurality of via plugs 56 provided on the interconnect layer 55, and a plurality of metal pads 57 provided on the plurality of via plugs 56. The metal pads 57 are, for example, a metal layer including a copper (Cu) layer. The circuit chip 22 functions as a logic circuit that controls operation of the array chip 21. The logic circuit is constituted by the transistors 51 and the like and electrically connected to the metal pads 57.

The array chip 21 includes a plurality of metal pads 61 provided on the plurality of metal pads 57, and a plurality of via plugs 62 provided on the plurality of metal pads 61. The metal pads 61 are, for example, a metal layer including a Cu layer. The array chip 21 also includes an interconnect layer 63 and an interconnect layer 64. The interconnect layer 63 includes a plurality of interconnects and is provided on the plurality of via plugs 62. The interconnect layer 64 includes a plurality of interconnects and is provided on the interconnect layer 63. The above-described bit line BL is included in the interconnect layer 64. The above-described logic circuit is electrically connected to the memory cell array 31 through the metal pads 61 and 57 and the like and controls operation of the memory cell array 31 through the metal pads 61 and 57 and the like.

The array chip 21 further includes a plurality of via plugs 65 provided on the interconnect layer 64, and a metal pad 66 provided on the plurality of via plugs 65 and the insulator 32. The array chip 21 also includes a passivation insulator 67 provided on the metal pad 66 and the insulator 32. The metal pad 66 is, for example, a metal layer including a Cu layer and functions as an external connection pad (bonding pad) of the semiconductor device of the present embodiment. The passivation insulator 67 is, for example, a stacked film including a SiO₂ film and a SiN film and has an opening P through which the upper face of the metal pad 66 is exposed. The metal pad 66 is electrically connectable to a mounting substrate or other devices through the opening P by a bonding wire, a soldering ball, a metal bump, or the like.

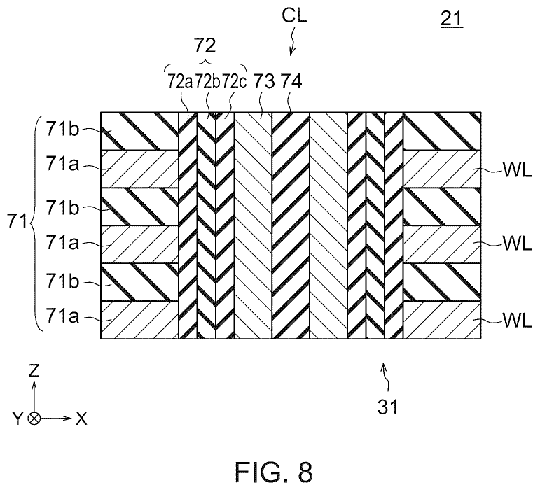

FIG. 8 is an enlarged cross-sectional view illustrating the structure of the semiconductor device of the second embodiment.

FIG. 8 illustrates the memory cell array 31 illustrated in FIG. 7. The memory cell array 31 includes a stacked film 71 including a plurality of electrode layers 71a and a plurality of insulators 71b alternately stacked in the Z direction. The plurality of electrode layers 71a function as, for example, the above-described word lines WL. Each electrode layer 71a is, for example, a metal layer including a MoSiN film (barrier metal layer) and a Mo layer (electrode material layer). Each insulator 71b is, for example, a SiO₂ film. The stacked film 71, the electrode layers 71a, and the insulators 71b of the present embodiment respectively correspond to the stacked film 12, the electrode layer 6, and the insulators 14 of the first embodiment.

FIG. 8 further illustrates one of the plurality of columnar portions CL illustrated in FIG. 7. Each columnar portion CL includes a memory insulator 72, a channel semiconductor layer 73, and a core insulator 74 sequentially provided on the side face of the stacked film 71. The memory insulator 72 includes a block insulator 72a, a charge storage layer 72b, and a tunnel insulator 72c sequentially provided on the side face of the stacked film 71. The block insulator 72a is, for example, a SiO₂ film. The charge storage layer 72b is, for example, an insulator such as a SiN film. The charge storage layer 72b may be a semiconductor layer such as a polysilicon layer. The charge storage layer 72b can store signal electric charge of the three-dimensional semiconductor memory. The tunnel insulator 72c is, for example, a SiO₂ film. The channel semiconductor layer 73 is, for example, a polysilicon layer. The channel semiconductor layer 73 functions as a channel of the three-dimensional semiconductor memory. The core insulator 74 is, for example, a SiO₂ film. The columnar portions CL of the present embodiment correspond to the columnar portions CL of the first embodiment.

The semiconductor device of the present embodiment may further include an insulator corresponding to the insulator 5b of the first embodiment.

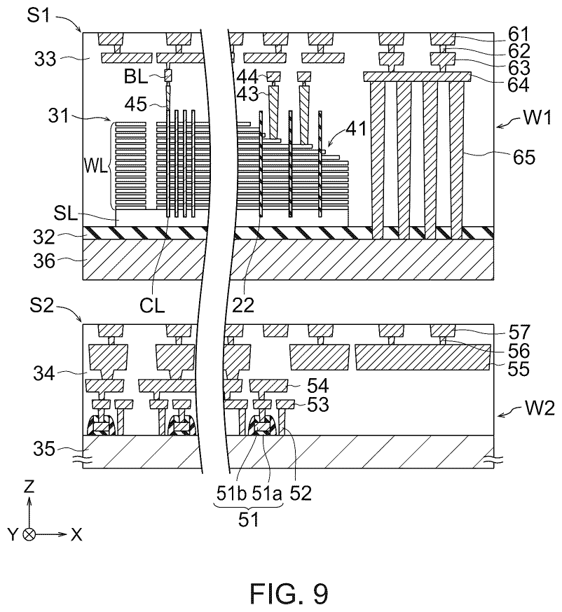

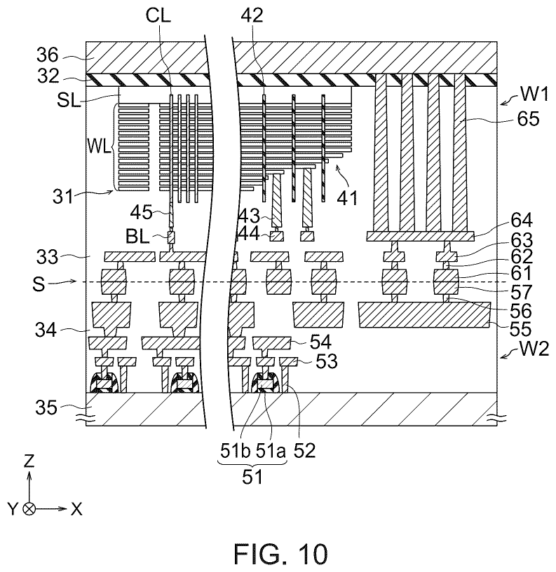

FIGS. 9 and 10 are cross-sectional views illustrating a method of manufacturing the semiconductor device of the second embodiment.

FIG. 9 illustrates an array wafer W1 including a plurality of array chips 21, and a circuit wafer W2 including a plurality of circuit chips 22. The orientation of the array wafer W1 in FIG. 9 is opposite the orientation of the array chip 21 in FIG. 7. In the present embodiment, the semiconductor device is manufactured by bonding the array wafer W1 and the circuit wafer W2. FIG. 9 illustrates the array wafer W1, the orientation of which is yet to be inverted for bonding, and FIG. 7 illustrates the array chip 21, the orientation of which is inverted for bonding and that is bonded and diced.

In FIG. 9, reference sign S1 denotes the upper face of the array wafer W1, and reference sign S2 denotes the upper face of the circuit wafer W2. The array wafer W1 includes a substrate 36 provided below the insulator 32. The substrate 36 is, for example, a semiconductor substrate such as a Si substrate. The substrate 36 of the present embodiment corresponds to the substrate 11 of the first embodiment.

In the present embodiment, first, the memory cell array 31, the insulator 32, the inter layer dielectric 33, the metal pads 61, the via plugs 65, and the like are formed on the substrate 36 of the array wafer W1, and the inter layer dielectric 34, the transistors 51, the metal pads 57, and the like are formed on the substrate 35 of the circuit wafer W2 as illustrated in FIG. 9. Subsequently, the array wafer W1 and the circuit wafer W2 are bonded to each other by mechanical pressure such that the face S1 and a face S2 face each other as illustrated in FIG. 10. Accordingly, the inter layer dielectric 33 and the inter layer dielectric 34 are bonded to each other. Subsequently, the array wafer W1 and the circuit wafer W2 are annealed. Accordingly, the metal pads 61 and the metal pads 57 are joined to each other. In this manner, the substrate 36 and the substrate 35 are bonded to each other through the inter layer dielectrics 33 and 34.

Thereafter, the substrate 36 is removed by chemical mechanical polishing (CMP) and the substrate 35 is thinned by CMP, and then the array wafer W1 and the circuit wafer W2 are disconnected into a plurality of chips (dicing). In this manner, the semiconductor device illustrated in FIG. 7 is manufactured. The metal pad 66 and the passivation insulator 67 are formed on the insulator 32 after the removal of the substrate 36 and the thinning of the substrate 35.

Although FIG. 7 illustrates the boundary face between the inter layer dielectric 33 and the inter layer dielectric 34 and the boundary face between the metal pads 61 and the metal pads 57, these boundary faces are typically not observed after the above-described annealing. However, the positions of the boundary faces can be estimated by detecting, for example, the tilt of the side face of both the metal pads 61 and the metal pads 57, and positional shift between the side face of the metal pads 61 and the side face of the metal pads 57.

The present embodiment makes it possible to apply the semiconductor device of the first embodiment and the method of manufacturing the same to the present embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a stacked film including a plurality of electrode layers and a plurality of first insulators that are alternately provided in a first direction; and
a columnar portion extending in the first direction in the stacked film, and including a charge storage layer provided on a side face of the stacked film via a second insulator, and a semiconductor layer provided on a side face of the charge storage layer via a third insulator,
wherein a first electrode layer among the plurality of electrode layers includes:
a first layer including molybdenum, nitrogen, and a Group 14 element; and
a second layer including molybdenum.

2. The device of claim 1, wherein the first layer further includes oxygen.

3. The device of claim 1, wherein the first layer further includes hydrogen.

4. The device of claim 1, wherein the first layer includes carbon or silicon as the Group 14 element.

5. The device of claim 1, wherein the first layer is a MoSiN film where Mo represents molybdenum, Si represents silicon, and N represents nitrogen.

6. The device of claim 5, wherein the first layer is the MoSiN film including oxygen as an impurity element.

7. The device of claim 5, wherein the first layer is the MoSiN film including hydrogen as an impurity element.

8. The device of claim 1, wherein an atomic concentration of nitrogen in the first layer is equal to or higher than 20% of an atomic concentration of molybdenum, nitrogen, and the Group 14 element in the first layer.

9. The device of claim 1, wherein an atomic concentration of the Group 14 element in the first layer is equal to or higher than 5% of an atomic concentration of molybdenum, nitrogen, and the Group 14 element in the first layer.

10. The device of claim 1, wherein an atomic concentration of hydrogen in the first layer is equal to or higher than 1.0×10²⁰ atoms/cm³.

11. The device of claim 1, wherein the first layer includes molybdenum as a main constituent element.

12. The device of claim 1, wherein a thickness of the first layer is equal to or smaller than 3 nm.

13. The device of claim 1, wherein the first layer is an amorphous layer.

14. The device of claim 1, wherein the second layer includes molybdenum as a main constituent element.

15. The device of claim 1, wherein the second layer is a Mo (molybdenum) layer.

16. The device of claim 1, wherein an atomic concentration of hydrogen in the second layer is higher than an atomic concentration of hydrogen in the second insulator.

17. The device of claim 1, wherein the first layer is a barrier metal layer, and the second layer is an electrode material layer.

18. The device of claim 1, wherein
the first electrode layer is provided between a lower-side insulator and an upper-side insulator among the plurality of first insulators,
the first layer is provided on an upper face of the lower-side insulator, a lower face of the upper-side insulator, and a side face of the second insulator, and
the second layer is provided on an upper face, a lower face, and a side face of the first layer.

19. The device of claim 18, wherein the first layer is provided on the upper face of the lower-side insulator, the lower face of the upper-side insulator, and the side face of the second insulator via a fourth insulator.

20. A method of manufacturing a semiconductor device, comprising:
forming a stacked film including a plurality of third layers and a plurality of first insulators that are alternately provided in a first direction;
forming a first concave portion extending in the first direction in the stacked film;
forming a columnar portion extending in the first direction in the stacked film by forming a charge storage layer on a side face of the stacked film in the first concave portion via a second insulator and forming a semiconductor layer on a side face of the charge storage layer in the first concave portion via a third insulator; and
replacing the plurality of third layers with a plurality of electrode layers,
wherein a first electrode layer among the plurality of electrode layers is formed to include:
a first layer including molybdenum, nitrogen, and a Group 14 element; and
a second layer including molybdenum.
